(19) United States
(12) Patent Application Publication
(10) Pub. No.: US 2002/0114271 A1
(43) Pub. Date: Aug. 22, 2002

(54) Restoring an interrupted switched connection

(76) Inventors: Thomas Happel, Puchheim (DE); Thomas Mekota, Freising (DE); Werner Lips, Munchen (DE); Pauls Markus, Munchen (DE)

Correspondence Address: FRANK R. OCCHIUTI, Fish & Richardson P.C., 225 Franklin Street, Boston, MA, 02110-2804, US

(21) Appl. No.: 10/033,000

(22) Filed: Oct. 25, 2001

(30) Foreign Application Priority Data
Nov. 22, 2000 (DE) 00125600.7

(51) Int. Cl. G01R 31/08

(52) U.S. Cl. 370/217; 370/225

(57) ABSTRACT

A system for restoring an interrupted switched connection between subscribers in a communications network includes a first transfer node for transmitting and receiving signals in the communications network, and a second transfer node for transmitting and receiving signals in the communications network. A network controller establishes a protected channel between the first and second transfer nodes, establishes a switched connection between the first and second transfer nodes in the protected channel, and restores the switched connection by restoring the protected channel if the switched connection is interrupted as a result of an interruption in the protected channel.

### CLAIM TO PRIORITY

This application claims priority to European Patent Application No. 00125600.7, filed on Nov. 22, 2000, the contents of which are hereby incorporated by reference into this application as if set forth herein in full.

### BACKGROUND

In communications networks, such as telephone networks, ATM (Asynchronous Transfer Mode) networks, or the Internet, a distinction is made between permanently existing connections—also referred to as “dedicated circuits” or “permanent connections” (PC)—and connections that are dynamically established at the start of network usage and that are cleared at the end of their use. The latter (i.e., non-permanent connections) are also referred to as “dial-up circuits” or “switched connections (SC)”.

### SUMMARY OF THE INVENTION

In general, in one aspect, the invention is directed to restoring an interrupted switched connection between subscribers in a communications network having first and second transfer nodes and a network controller. This aspect features establishing, via the network controller, a protected channel between the first and second transfer nodes, and establishing a switched connection between the first and second transfer nodes in the protected channel. If the switched connection is interrupted as a result of an interruption in the protected channel, this aspect of the invention further includes restoring the switched connection by restoring the protected channel. This aspect may also include one or more of the following features.

The protected channel may include a path that can accommodate a plurality of switched connections. An interruption in the switched connection may be detected and the protected channel may be restored following the interruption in the switched connection. The protected channel may be a soft permanent connection. The protected channel may be established in accordance with standard Q.2767.1 (05/98) and/or standard AF-PNNI-0055.000 (03/96).

An unprotected channel may be established in parallel with the protected channel. The switched connection between the first and second transfer nodes may be established in one of the protected channel and the unprotected channel. The invention may decide in which of the protected channel and the unprotected channel to establish the switched connection between the first and second transfer nodes. A sub-path may exist between the first and second transfer nodes, through which a signal is transmitted from the first transfer node to the second transfer node. The decision of where to establish the switched connection may be made in the first node.

The protected channel may be autonomously and independently established by the communications network.

Other features and advantages of the invention will become evident from the description, drawings and claims.

### DESCRIPTION OF THE DRAWING

FIG. 1 is a block diagram that shows a communications network having a protected channel.

### DESCRIPTION

Permanent connections may be established by control instructions originating from central network management. Individual control instructions can either be issued to all relevant network nodes along a permanent connection—in ATM networks, connections set up in this way are referred to as “permanent virtual connections (PVC)”—or the control instructions can be issued to one node only, indicating the start and destination point of the required connection. In the latter case, the one node then sets up the connection using special signaling, hereinafter also referred to as “PC signaling”. Connections set up in this way are referred to as “soft PVC (SPVC)” in ATM networks. PC signaling is carried out here, for example:

according to the recommendations of the ITU-T with the Q.2761 to Q.2764 (02/95) series protocol, “B-ISUP (Broadband ISDN User Part) Basic Call”, extended according to Q.2767.1 (05/98), “soft PVC Capability”, Sections 1, 5 and 6, for setting up SPVCs, or

according to the recommendation of the ATM Forum AF-PNNI-0055.000 (03/96), “Private Network-Network Interface”, Sections 6.4.6.1, 6.4.6.2 and Annex C.

In the extended protocol for SPVCs, in particular (1) the address of the end point of the SPVC and (2) an identifier for relocating interrupted sub-connections are transferred to the node. In ATM networks, this method can also be used for setting up an entire path (e.g., a connection). In this case, “Permanent Virtual Paths (PVP)” or “soft PVP (SPVP)” arise. PCs set up according to the special Soft PVC or Soft PVP method are also referred to as “soft PCs (SPC)”.

Permanent connections can have the following characteristics:

PCs are set up based on control instructions provided by network management.

PCs can be set up as “Protected PCs (PPC)”. Two ways to implement the PPC are: 1) an alternative path is set up in advance, for switchover if required; 2) if a PC fails, it is automatically restored (soft PCs are therefore, by definition, PPCs). In both cases, subscribers can, for their part, continue to use the PC without further intervention following the protection switching.

Apart from the PC, no additional signaling connection exists for the duration of the connection between the subscribers, i.e., apart from the data signal exchange, no accompanying signaling data can be exchanged between the subscribers. In ATM networks, a (PC) signaling connection exists if required in the case of a Soft PC between the start and end node of the Soft PC, but not between the subscribers.

A fixed allocation exists between the start and end point. Subscribers have no selection facility.

Switched connections are set up through control instructions of the subscriber by general signaling (hereinafter also referred to in the context of this application as “SC signaling” to distinguish it from PC signaling) at the time the subscriber wishes to use the connection and to the destination which the subscriber specifies. The connection is cleared at the end of use at the request of one of the subscribers.

In ATM networks, connections of the foregoing type are referred to as “switched VCs (SVC)” and paths of this type are referred to as “switched VPs (SVP)”. The SC signaling is carried out here e.g. with protocol elements of the aforementioned Q.2761 to Q.2764 series, “B-ISUP (Broadband ISDN User Part) Basic Call” and the recommendation AF-PNNI-0055.000, “Private Network-Network Interface”.

Switched connections have the following characteristics:

SCs are set up following control instructions of the subscribers.

In the event of failure of the SC or part thereof, the entire SC is destroyed and can no longer be used. Heretofore, no automatic restoration took place. Subscribers must identify the SC failure themselves and, if necessary, request the setting up of a new SC.

During the connection set-up and for the duration of the connection, an (SC) signaling connection, via which the subscribers (or in parallel therewith the network operators) can exchange information with one another, also exists between the subscribers in addition to the SC. Typical information is, for example, the address of the calling subscriber (e.g. IP address or telephone number), address of the called subscriber, charge information.

There is no fixed allocation between the start and end point of the connection. The subscriber requesting an SC can freely select the end point of the SC by specifying the B telephone number.

In contemporary networks, SCs and PCs are administered in different ways according to the different characteristics.

PCs normally are comprised of three segments: 1) the segment S1_{PC} between the A-subscriber and his allocated transfer node Ü_{A}, 2) the segment S2_{PC} between the B-subscriber and his allocated transfer node Ü_{B}, 3) the segment S3_{PC} between the two transfer nodes Ü_{A} and Ü_{B}. The first two segments S1_{PC}, S2_{PC} are normally allocated to the “access network”. The third segment S3_{PC} is part of the “core network”. If required, this sub-unit is also designed as a protected PC, e.g. in the case of a PC between two central mainframe computers of a bank.

SCs similarly are comprised of three segments: 1) the segment S1_{SC} between the A-subscriber and his allocated switching node V_{A}, 2) the segment S2_{SC} between the B-subscriber and his allocated switching node V_{B}, 3) the segment S3_{SC} between the two switching nodes V_{A} and V_{B}. The first two segments S1_{SC}, S2_{SC}, are similarly allocated to the access network. The third segment S3_{SC} is similarly part of the core network. However, unlike the PCs, the third segment S3_{SC} is not designed in existing telephone networks as a protected connection, since a multiplicity of alternative paths would have to made available here as a precaution, all requiring the same bandwidth as the main paths and having to be kept unoccupied and unused. Resource-intensive protection of this type is implemented for selected individual PCs only, but is not suitable as a general protection concept for a multiplicity of SCs. The segment S3_{SC} of an SC is essentially implemented in the core network as an unprotected SC.

The problem is therefore that the advantages of the PCs—secure availability through automatic restoration—and the advantages of the SCs—signaling and targeted partner selection—cannot be used simultaneously.

BTD-CS-REROUTE-01.04, “Edge-based rerouting for point-to-point calls version 1.0 (baseline text document)”, a working paper of the ATM Forum, proposes a method for solving this problem, in which the signaling protocol AF-PNNI-0055.000, “Private Network-Network Interface”, is extended to control SCs. Definition and implementation of corresponding protocol information elements and procedures is intended to enable individual SCs to be restored in segments between two nodes in the network following a failure. However, supplementing the standardized signaling protocols is a laborious process, since the supplements first have to be developed and agreed by the corresponding bodies. Furthermore, in the event of a failure in a broadband path containing a multiplicity of SCs, separate restoration is required for each affected SC, resulting in a substantial load on the network from the signaling messages.

One object of the invention is therefore to devise a concept for restoring switched connections, which is improved compared with the method proposed in BTD-CS-REROUTE-01.04.

Here, there is no need to supplement standardized (SC) signaling protocols with parameters to set up a protected channel, since at least one protected channel is set up in the communications network between two transfer nodes on at least one sub-path by a network controller and not by the standardized (SC) signaling protocol. A first subscriber is allocated to the first transfer node and a second subscriber is allocated to the second transfer node.

With appropriate design of the protected channel, the signaling outlay required to restore interrupted switched connections established in the protected channel is significantly reduced since, in the event of interruption in the switched connections as a result of an interruption in the protected channel, only the protected channel is restored, and not the interrupted switched connections.

Particularly useful advantages are gained if the restoration following a failure is performed by the network itself, autonomously and independently, i.e., without intervention on the part of an operator (TMN) or user (user signaling). In a correspondingly high-performance implementation of the restoration, automatic cleardown of switched connections existing along the failed sub-path effected by the terminal devices can be prevented here. This occurs if the restoration time for the protected channels is shorter than the response time of the terminal devices to the failure in the protected channel.

Along with these advantages, the invention offers further substantial advantages, some of which will be presented below:

The invention is vendor-independent. All nodes that can handle the standardized SCs and PCs can use the method in a multi-vendor environment.

The invention can be introduced immediately. It requires virtually no supplementing of the signaling protocols, since it is based on existing, standardized protocol elements and procedures. The invention can generally be used with no software upgrade in all transfer nodes of the core network.

Since the protected channel can also be set up on one sub-path only, the use of protected channels can be adapted in a highly flexible manner to different requirements concerning the reliability of the switched connections which arise in different segments of the communications network. Thus, for example, in areas at risk from earthquakes (e.g. the west coast of the USA), significantly more switched connections could be routed via protected lines than in other areas (e.g. the east coast of the USA).

According to one embodiment of the invention, the protected channel is designed as a path in which a plurality of switched connections can be established. This results in a significant reduction in the signaling outlay in the event of an interruption, since only the interrupted path, but not the switched connections contained therein, needs to be restored.

In one embodiment of the invention, the protected channel is restored following an interruption. The protected channel may be designed as a soft permanent connection. There is therefore no longer any need for the precautionary use of alternative paths, since these are set up only if required. This offers the advantage that, in the normal case, i.e., without connection interruption, no network resources need to be reserved for alternative paths.

In another embodiment, the protected channel is established with the aid of protocol elements and procedures that are designed according to those of standard Q.2767.1 (05/98) and/or those of standard AF-PNNI-0055.000 (03/96). These standards already define information elements and procedures in order to address end points, and also to relocate existing sub-connections within the node. Protocol elements of existing standards do not need to be modified.

According to another embodiment of the invention, it is provided that, in at least one further unprotected channel set up in parallel with the protected channel between the two transfer nodes, the switched connection is set up in either the protected or the unprotected channel. Here, it is provided, in particular, that the channel in which the switched connection is set up is selected on the basis of at least one selection criterion. A targeted selection of the switched connections that are to be routed via protected channels and those which are to be routed via unprotected channels can thus be made by the network operator. Various selection criteria can be used here, e.g. a first telephone number, a second telephone number, a category of the calling subscriber (priority subscriber) and/or the origin of the connection.

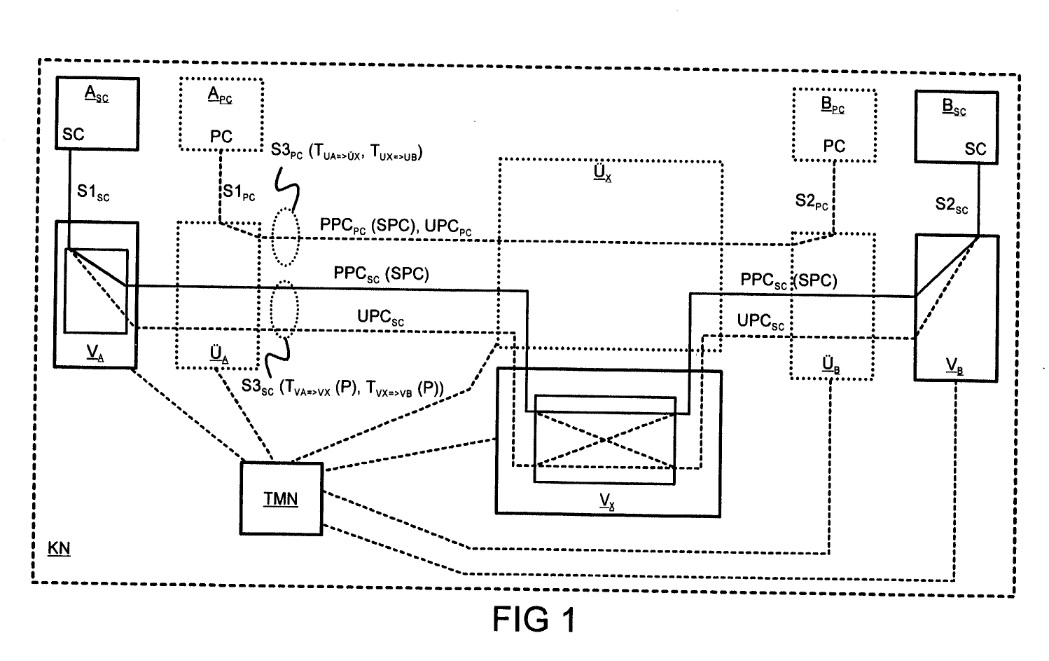

Referring now to FIG. 1, FIG. 1 shows a communications network KN. The communications network includes a plurality of transfer nodes V_{A}, V_{B}, V_{X}, Ü_{A}, Ü_{B}, Ü_{X}, whereby the transfer nodes Ü_{A}, Ü_{B}, Ü_{X} are designed as transmission nodes Ü. A subscriber A_{SC} is allocated to the transfer node V_{A}, a subscriber B_{SC} is allocated to the transfer node V_{B}, a subscriber A_{PC} is allocated to the transmission node Ü_{A}, and a subscriber B_{PC} is allocated to the transmission node Ü_{B}. A switched connection SC is provided between the subscribers A_{SC}, B_{SC} and a permanent connection PC is provided between the subscribers A_{PC}, B_{PC}. The permanent connection PC, the transmission nodes Ü, and the subscribers A_{PC}, B_{PC} serve merely to provide a clearer understanding of the interplay between switched connections SC and permanent connections PC. However, they are not essential components of the invention and are therefore shown by dotted lines.

Both connections SC, PC are roughly divided up into three logical segments: 1) in each case one segment S1 between the relevant subscriber A and his respective allocated transfer node V_{A} or Ü_{A}, 2) in each case one segment S2 between the relevant subscriber B and his respective allocated transfer node V_{B} or Ü_{B}, and 3) in each case one segment S3 between the two transfer nodes V_{A} and V_{B} or Ü_{A} and Ü_{B}.

The third segment S3 comprises, for example, in each case two sub-paths T, the first sub-path T_{VA=>VX} or T_{ÜA=>ÜX} being provided between the two transfer nodes V_{A} and V_{X} or Ü_{A} and Ü_{X} and a second sub-path T_{VX=>VB} or T_{ÜX=>ÜB} being provided between transfer nodes V_{X} and V_{B} or Ü_{X} and Ü_{B}.

The sub-paths T of the third segment S3_{PC} of the permanent connection PC are either designed as a protected channel PPC_{PC} or as an unprotected channel UPC_{PC}, depending on whether the subscribers A_{PC}, B_{PC} have applied for a protected or an unprotected permanent connection PC.

At least one of the sub-paths T of the third segment S3_{SC} of the switched connection SC is designed according to the invention as a protected channel PPC_{SC}, i.e., the switched connection SC is set up on this sub-path T essentially in the protected channel PPC_{SC}. Moreover, a further, unprotected channel UPC_{SC}, which runs in parallel with the protected channel PPC_{SC}, is optionally provided in one embodiment of the invention. In this case, the switched connection SC may also optionally be set up in the unprotected channel UPC_{SC} rather than in the protected channel PPC_{SC}. This selection as to whether to set up the connection in the protected or unprotected channel is made in a third segment S3_{SC}, which comprises only one single sub-path T, preferably in the transfer node V_{A}. Insofar as the third segment S3_{SC} comprises a plurality of sub-paths T_{VA=>VX}, T_{VX=>VB}, the selection is made, if necessary, in more than one transfer node V. In particular, a switched connection SC, which has been set up on the sub-path T_{VA=>VX} in the protected channel PPC_{SC}, can be set up on the sub-path T_{VX=>VB} in the unprotected channel UPC_{SC} and vice versa. This situation is shown in the transfer node Vx.

The protected channel PPC may be implemented as a soft permanent connection SPC. In the event that an interruption is detected in the SPC, the SPC is restored automatically, i.e., with no intervention on the part of the subscribers A, B or the network management TMN, in accordance with standard ITU-T Recommendation Q.2767.1, “soft PVC capability” or the ATM Forum Recommendation AF-PNNI-0055.000, “Private Network-Network Interface”.

Furthermore, a network controller TMN may be allocated to all transfer nodes V, Ü. Permanent connections PC are normally set up by this network controller between the transfer nodes V, Ü of the communications network KN with the aid of control instructions and, if necessary, e.g. in the event of an interruption, are also restored by the network controller depending on the type of permanent connection.

In one embodiment of the invention, at least one protected channel PPC_{SC} is initially set up by the network controller TMN between transfer nodes V_{A}, V_{B}, V_{X}. The switched connection SC is then dynamically set up immediately before the start of its use. Here, it is set up on at least one sub-path T of the segment S3_{SC} in the protected channel PPC_{SC}.

In the event that an interruption in the switched connection SC is detected following an interruption in the protected channel PPC_{SC}, the protected channel PPC_{SC} rather than the interrupted switched connection SC itself is restored. Particularly useful advantages here are associated with a protected channel PPC_{SC} which is designed as a path P in which a plurality of switched connections SC can be set up. In this case, the signaling outlay required for the restoration is reduced, since only the interrupted path P, but not the switched connections SC, needs to be restored.

If the protected channel is designed as a soft permanent connection SPC, no extension of existing standards is required, insofar as, in the event of an interruption, the restoration is carried out with the aid of protocol elements and procedures which are designed according to those of the standard Q.2767.1 and/or those of the standard AF-PNNI-0055.000.

Following a failure of the network itself, the restoration can be carried out autonomously and independently, i.e. with no intervention on the part of an operator (TMN) or user (user signaling). Alternatively, the restoration could also be controlled and carried out by the network management TMN. Restoration by the user by means of user signaling is also possible.

In a correspondingly high-performance implementation of the restoration, automatic cleardown of switched connections existing along the failed sub-path effected by the terminal devices can be prevented. This occurs if the restoration time for the protected channel is shorter than the response time of the terminal devices to the failure of the protected channel.

If an SVC currently fails, it is assumed that the subscribers (or equipment) will respond, e.g., by clearing (tearing down) existing connections and, if necessary, by initiating a restoration. Statistically calculable (or, in the case of equipment, settable) response times exist for this behavior. For interworking between the invention and contemporary terminal devices, the restoration time would appropriately have to be in the ˜50 ms range.

However, if one moves slightly further away from current PVC and SPVC concepts and, in quite general terms, assumes a prospective, substantially improved concept of a protected channel, the described response in the terminal devices could also be dispensed with, thereby advantageously simplifying said terminal devices.

If, according to an embodiment of the invention, at least one further unprotected channel UPC_{SC} is provided in parallel with the protected channel PPC_{SC}, the switched connection SC can optionally be set up in the unprotected channel UPC_{SC} rather than in the protected channel PPC_{SC}. This selection is preferably made on the basis of a selection criterion, e.g. the telephone number of the subscriber A_{SC}, the telephone number of the subscriber B_{SC}, the category of the calling subscriber—e.g. subscriber A_{SC}—and/or the origin of the connection. The selection is made during the connection set-up by the subscriber A_{SC} preferably in the switching node V_{A}, since the subscriber A_{SC} is allocated to this node.

Finally, it is noted the invention is not limited to the specific embodiments, structure and methods described herein. For example, the components, e.g. the protected channels PPC, can be implemented in any given designs and with any given means, i.e. even with previously provided alternative routes.

Other embodiments not described herein are also within the scope of the following claims.

What is claimed is:

1. A method for restoring an interrupted switched connection between subscribers in a communications network having first and second transfer nodes and a network controller, the method comprising:
establishing, via the network controller, a protected channel between the first and second transfer nodes; and
establishing a switched connection between the first and second transfer nodes in the protected channel;
wherein, if the switched connection is interrupted as a result of an interruption in the protected channel, the method further comprises restoring the switched connection by restoring the protected channel.

2. The method of claim 1, wherein the protected channel comprises a path that can accommodate a plurality of switched connections.

3. The method of claim 1, further comprising:
detecting an interruption in the switched connection; and
restoring the protected channel following the interruption in the switched connection.

4. The method of claim 1, wherein the protected channel comprises a soft permanent connection.

5. The method of claim 1, wherein the protected channel is established in accordance with at least one of standard Q.2767.1 (05/98) and standard AF-PNNI-0055.000 (03/96).

6. The method of claim 1, further comprising:
establishing an unprotected channel in parallel with the protected channel;
wherein the switched connection between the first and second transfer nodes can be established in one of the protected channel and the unprotected channel.

7. The method of claim 6, further comprising:
deciding in which of the protected channel and the unprotected channel to establish the switched connection between the first and second transfer nodes.

8. The method of claim 7, wherein a sub-path exists between the first and second transfer nodes through which a signal is transmitted from the first transfer node to the second transfer node, and wherein deciding is performed in the first transfer node.

9. The method of claim 1, wherein the protected channel is autonomously and independently established by the communications network.

10. A system for restoring an interrupted switched connection between subscribers in a communications network, the system comprising:
a first transfer node for transmitting and receiving signals in the communications network;
a second transfer node for transmitting and receiving signals in the communications network; and
a network controller which establishes a protected channel between the first and second transfer nodes, establishes a switched connection between the first and second transfer nodes in the protected channel, and restores the switched connection by restoring the protected channel if the switched connection is interrupted as a result of an interruption in the protected channel.

11. The system of claim 10, wherein the protected channel comprises a path that can accommodate a plurality of switched connections.

12. The system of claim 10, wherein the network controller:
detects an interruption in the switched connection; and
restores the protected channel following the interruption in the switched connection.

13. The system of claim 10, wherein the protected channel comprises a soft permanent connection.

14. The system of claim 10, wherein the protected channel is established in accordance with at least one of standard Q.2767.1 (05/98) and standard AF-PNNI-0055.000 (03/96).

15. The system of claim 10, wherein:
the network controller establishes an unprotected channel in parallel with the protected channel; and
the switched connection between the first and second transfer nodes can be established in one of the protected channel and the unprotected channel.

16. The system of claim 15, wherein first transfer node decides in which of the protected channel and the unprotected channel to establish the switched connection between the first and second transfer nodes.

17. The system of claim 16, wherein a sub-path exists between the first and second transfer nodes through which a signal is transmitted from the first transfer node to the second transfer node.

18. The system of claim 10, wherein the protected channel is autonomously and independently established by the communications network.
